(19) United States
(12) Patent Application Publication
(10) Pub. No.: US 2025/0168051 A1
(43) Pub. Date: May 22, 2025

(54) RECEIVER ARCHITECTURE DEMODULATING 4N-QAM DIRECTLY IN ANALOG DOMAIN WITHOUT ANALOG-TO-DIGITAL CONVERTER (ADC)

(71) Applicant: THE REGENTS OF THE UNIVERSITY OF CALIFORNIA, Oakland, CA (US)

(72) Inventors: Huan Wang, Irvine, CA (US); Payam Heydari, Irvine, CA (US)

(21) Appl. No.: 19/026,969

(22) Filed: Jan. 17, 2025

Related U.S. Application Data
(63) Continuation of application No. PCT/US23/28245, filed on Jul. 20, 2023.
(60) Provisional application No. 63/391,616, filed on Jul. 22, 2022.

(51) Int. Cl. H04L 27/26

(52) U.S. Cl. CPC H04L 27/2649; H04L 27/2655

(57) ABSTRACT

Disclosed are example embodiments of a receiver. The receiver including a front-end amplification and filtering block configured to amplify a received signal and filter out a potential jammer signal from a communication channel. The receiver also including a quadrature mixer, coupled to the front-end amplification and filtering block, and configured to down-convert the amplified and filtered signal to baseband to generate a quadrature LO signal. Additionally, the receiver including a carrier synchronization loop configured to synchronize the quadrature LO signal and carrier phase of the received signal. The receiver also including a demodulator coupled to the quadrature mixer and the carrier synchronization loop.

### CROSS-REFERENCE TO RELATED APPLICATIONS

This application is a continuation of International Patent Application Serial No. PCT/US23/28245, filed Jul. 20, 2023, which claims the benefit of priority under 35 U.S.C. § 119(e) from U.S. Provisional Application Ser. No. 63/391,616, filed Jul. 22, 2022, both of which are hereby incorporated by reference in their entireties for all purposes.

### TECHNICAL FIELD

The disclosure relates generally to the field of receiver architecture for ultra-high-speed communication, and specifically and not by way of limitation, some embodiments are related to a receiver architecture that employs a carrier synchronization loop and high-speed pipelined structure to directly demodulate high order QAM signal into raw bitstreams.

### BACKGROUND

High-speed receivers are widely used in scenarios such as wireless front-haul/back-haul in 5G and future 6G (and next-G) wireless networks, coherent optical communications, etc. To boost the communication speed above 100 Gbps, more than an order of magnitude higher than what can be achieved by commercial technologies today, receivers must handle ultra-high-speed signals with high-order modulation schemes. The analog-to-digital converter (ADC) in conventional receiver realizations quickly become the bottleneck, significantly limiting the speed, power consumption and cost of entire communication link. For example, a 64-quadrature amplitude modulated (QAM) signal has to be clocked at 16.7 GBaud to achieve 100 Gbps data rate, requiring more than 33 GHz of instantaneous bandwidth. The ADC in such a system using conventional architecture has to sample at a minimum rate of 33 GSa/s, with 10bit resolution or higher. An ADC with such an extremely high sampling rate and high resolution can be found in high-end instrumentation (real-time oscilloscope Keysight UXR1104A). Such data acquisition system involves a combination of proprietary III-V front-end technology, massive time-interleaving and complicated calibration algorithms in the background to achieve the stated performance level. This implies low yield, high cost, multi-watts of power, and very bulky system implementation, which all work against the requirements for “beyond-5G” wireless and next-generation power-efficient wireline systems. Therefore, resolving the ADC bottleneck in conventional high-speed receiver architecture is foremost in pushing the upper limit of communication data rate.

### SUMMARY

In one example implementation, an embodiment includes a carrier synchronization loop so that the quadrature LO signal is generated in synchronization with the carrier phase of a received signal.

Disclosed are example embodiments of a receiver. The receiver including a front-end amplification and filtering block configured to amplify a received signal and filter out a potential jammer signal from a communication channel. The receiver also including a quadrature mixer, coupled to the front-end amplification and filtering block, and configured to down-convert the amplified and filtered signal to baseband to generate a quadrature LO signal. Additionally, the receiver including a carrier synchronization loop configured to synchronize the quadrature LO signal and carrier phase of the received signal. The receiver also including a demodulator coupled to the quadrature mixer and the carrier synchronization loop.

The features and advantages described in the specification are not all-inclusive. In particular, many additional features and advantages will be apparent to one of ordinary skill in the art in view of the drawings, specification, and claims. Moreover, it should be noted that the language used in the specification has been principally selected for readability and instructional purposes and may not have been selected to delineate or circumscribe the disclosed subject matter.

### BRIEF DESCRIPTION OF THE DRAWINGS

The foregoing summary, as well as the following detailed description, is better understood when read in conjunction with the accompanying drawings. The accompanying drawings, which are incorporated herein and form part of the specification, illustrate a plurality of embodiments and, together with the description, further serve to explain the principles involved and to enable a person skilled in the relevant art(s) to make and use the disclosed technologies.

FIG. 1 is a diagram illustrating a proposed receiver architecture with the annotated signal flow in accordance with the systems and methods described herein.

FIG. 2 is a diagram illustrating a 64-QAM Illustration of PQD Operation Principle in accordance with the systems and methods described herein.

FIG. 3. is a diagram illustrating a proposed 3-stage implementation of PQD to demodulate 64-QAM signal in accordance with the systems and methods described herein.

FIG. 4 is a diagram illustrating an N-stage PQD for the demodulation of 4N-QAM in accordance with the systems and methods described herein.

FIG. 5 is a diagram illustrating a carrier phase synchronization and down-converted baseband signal waveform in accordance with the systems and methods described herein.

FIG. 6 is a diagram illustrating a baseband signal in each stage of PQD illustrating a demodulation process of a 64QAM Signal in accordance with the systems and methods described herein.

FIG. 7 is a flowchart illustrating an example method in accordance with the systems and methods described herein.

The figures and the following description describe certain embodiments by way of illustration only. One skilled in the art will readily recognize from the following description that alternative embodiments of the structures and methods illustrated herein may be employed without departing from the principles described herein. Reference will now be made in detail to several embodiments, examples of which are illustrated in the accompanying figures. It is noted that wherever practicable similar or like reference numbers may be used in the figures to indicate similar or like functionality.

### DETAILED DESCRIPTION

The detailed description set forth below in connection with the appended drawings is intended as a description of configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

Several aspects of example systems will now be presented with reference to various apparatus and methods. These apparatus and methods will be described in the following detailed description and illustrated in the accompanying drawings by various blocks, components, circuits, processes, algorithms, etc. (collectively referred to as “elements”). These elements may be implemented using various components, hardware, electronic hardware, computer software, or any combination thereof. Whether such elements are implemented as hardware or software depends upon the particular application and design constraints imposed on the overall system.

An example embodiment includes a receiver architecture for ultra-high-speed communication.

An example embodiment includes a receiver architecture that employs a carrier synchronization loop and high-speed pipelined structure to demodulate high-order QAM signal into raw bitstreams directly. The example receiver does not require an analog-to-digital converter (ADC) in the signal path.

An example embodiment aims to resolve an ADC bottleneck in conventional high-speed QAM receivers by employing a signal demodulation architecture free of a high-speed-resolution ADC in the signal path. The receiver may be capable of demodulating any 4N-QAM signal at any arbitrary carrier frequency, where N is an integer (e.g., 1, 2, 3, . . . ). The receiver architecture may include a front-end amplification and filtering stage, a quadrature down-conversion mixer whose local oscillator (LO) signal comes from a carrier synchronization loop. The down-converted quadrature baseband signals may feed a pipelined QAM demodulator (PQD) to convert a baseband (BB) 4N-QAM constellation into 2N lanes of non-return-to-zero (NRZ) bitstreams. Channel equalization and symbol clock recovery may be included in the PQD.

In an example embodiment, the 4N-QAM signal demodulation does not involve any high-speed-resolution ADCs. An example embodiment may only require 2N high-speed “sign-check” comparators, which in some examples may be much more energy-efficient and cost-effective. The communication speed can be drastically improved due to the removal of the high-speed-resolution ADC bottleneck. An example embodiment may find wide application in wireless and next-generation wireline systems that may require ultra-high data rates.

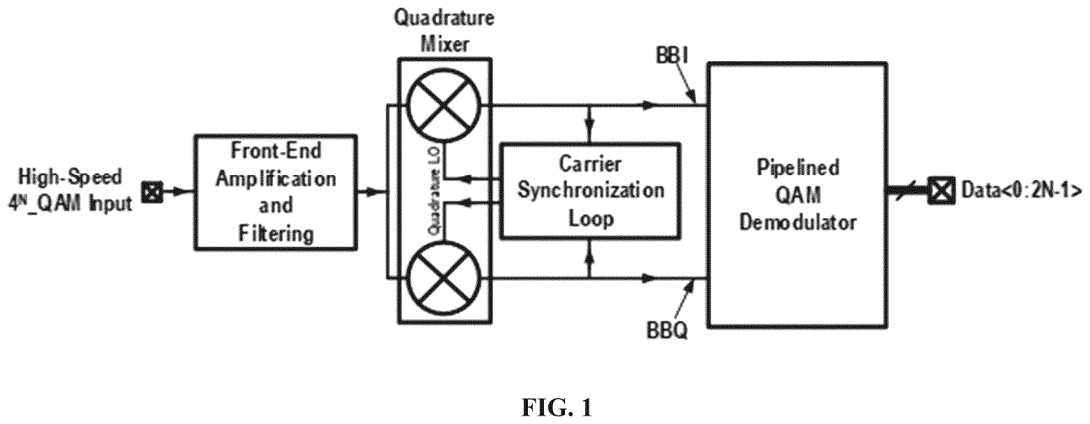

FIG. 1 is a diagram illustrating a proposed receiver architecture with the annotated signal flow in accordance with the systems and methods described herein. The incoming high-speed 4N-QAM signal may first be processed by front-end amplification and filtering block to enlarge the signal with minimum added noise and filter out potential jammer signals from the communication channel. The amplified and filtered signal enters a quadrature mixer to be down-converted to baseband. Unlike in conventional receiver architecture, where the quadrature LO signal is generated irrespective of the carrier phase of the modulated QAM signal, the invented receiver uses a carrier synchronization loop. The quadrature LO signals feeding the mixer may track the carrier phase of the modulated QAM signal. The down-converted baseband signals (BBI and BBQ in FIG. 1) feed the PQD and produce 2N lanes of NRZ bit streams at symbol baud rate of the modulated QAM signal. By employing the carrier synchronization loop, the signals at mixer baseband output (node BBI and BBQ in FIG. 1) may be a pulse-amplitude-modulated (PAM)-2N with maximum eye openings, which is critical for the proper operation of the following PQD. The realization of the carrier-synchronization loop may be based on the classic Costas loop.

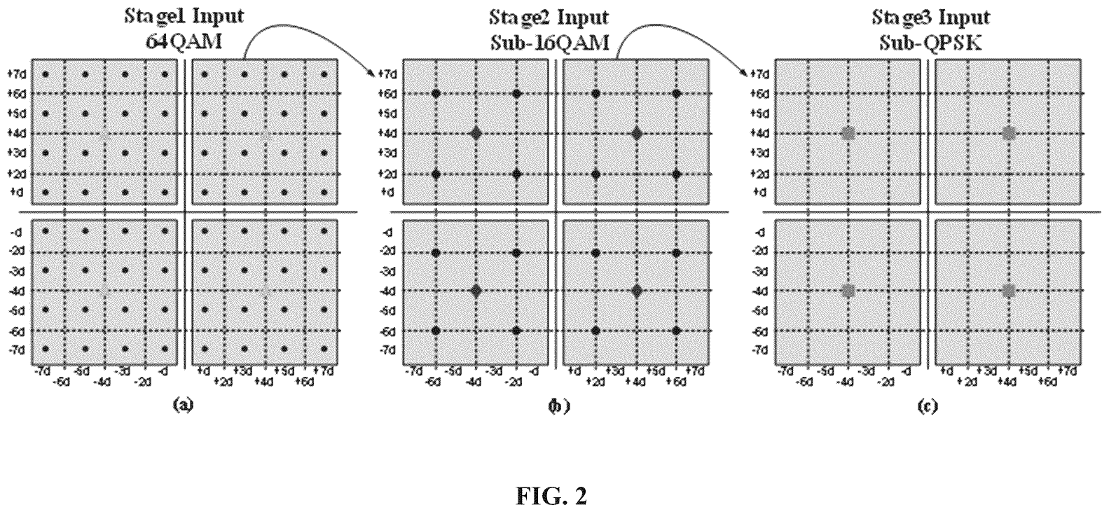

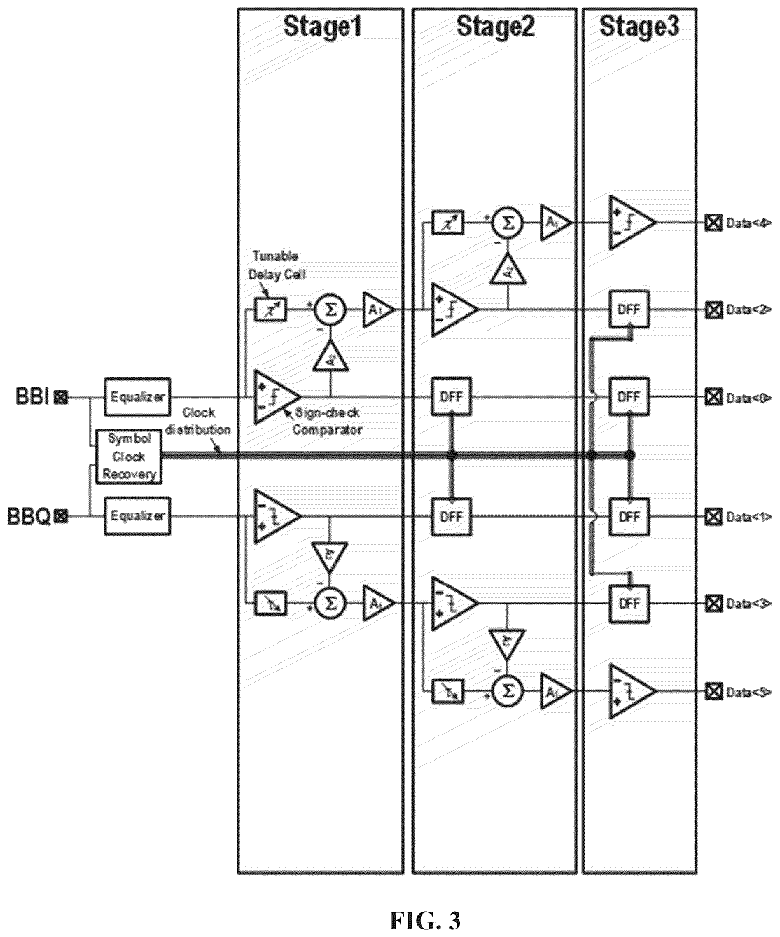

FIG. 2 is a diagram illustrating a 64-QAM Illustration of PQD Operation Principle in accordance with the systems and methods described herein. FIG. 3. is a diagram illustrating a proposed 3-stage implementation of PQD to demodulate 64-QAM signal in accordance with the systems and methods described herein. The principle of operation of PQD may be explained by the constellation in FIG. 2. Without loss of generality, an example embodiment may use a 64-QAM signal as one example. The corresponding 3-stage implementation to demodulate 64-QAM signal is illustrated in FIG. 3.

First, the equalizers equalize these in-phase and quadrature baseband PAM signals to remove any channel-induced inter-symbol-interference (ISI) effect. In an example embodiment, the baseband signals (BBI and BBQ in FIG. 1) may constitute a complex baseband 64-QAM constellation, while BBI/BBQ may be PAM-8 waveforms by themselves. Implementing an equalizer can be arbitrary depending on the communication channel property. Possible options include but are not limited to continuous-time-linear-equalizer (CTLE), feedforward-equalizer (FFE), and decision feedback equalizer (DFE).

In an example embodiment, the received symbol may be any one of the 64 constellation points indicated in circle dots in FIG. 2 (a). By feeding the equivalent complex baseband 64-QAM constellation to a pair of sign-check comparators in stage1 (shown in FIG. 3), the located quadrant of the received symbol can be determined, which results in the demodulation of 2-bit data (Data<0> and Data<1> in FIG. 3). Depending on the demodulated bits from stage 1, the sub-16QAM constellation in each quadrant may be moved to the center of the complex plane by subtracting the center point of each quadrant (denoted by triangle dots in FIG. 2(a)). The sub-16QAM constellation in each quadrant may be moved to the center of the complex plane by subtracting the center point of each quadrant, which in turn results in an equivalent complex baseband 16-QAM constellation that will feed stage 2.

In an example embodiment, the proper subtraction in stage 1 that converts 64-QAM into 16QAM constellation is performed by a tunable delay cell, a limiting amplifier A2, a summer, and a precision gain amplifier A1 in FIG. 3. The limiting amplifier A2 has a saturated output equal to the normalized value of 4d, as indicated in FIG. 2. The A2 amplifier limit is adjusted dynamically based on the received signal strength and may track the normalized value of 4d. The tunable delay cell may be used to match the propagation delay of the sign-check comparator such that the signals that arrive in the summer are perfectly aligned in the time domain, thus avoiding signal glitches or errors. Upon subtraction performed by the summer, a sub-16QAM constellation is formed with a maximum amplitude of 3d. A precision gain amplifier Al with a typical gain of 2 further amplifies the sub-16QAM constellation to relax the speed-accuracy requirement of the following stages. A similar operation is performed again in stage2 to convert the sub-16QAM constellation into a sub-QPSK constellation feeding stage3. The final stage3 only needs a sign-check comparator to demodulate the final 2 bits (Data<4> and Data<5> in FIG. 3).

To demodulate data bits from earlier stages are buffered and re-timed by D-flip-flops (DFF) in subsequent stages. The final demodulated 6b data streams are aligned by the same clock edge driving DFFs in stage3. The clock signal that drives the DFFs is recovered from the baseband signals using a symbol clock recovery loop with clock distribution annotated in FIG. 3.

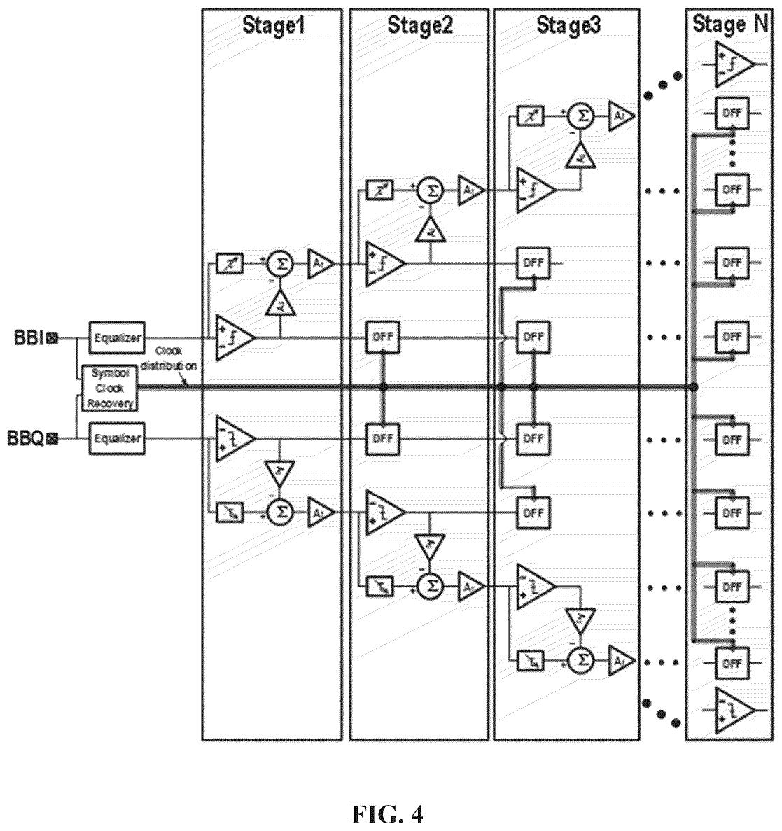

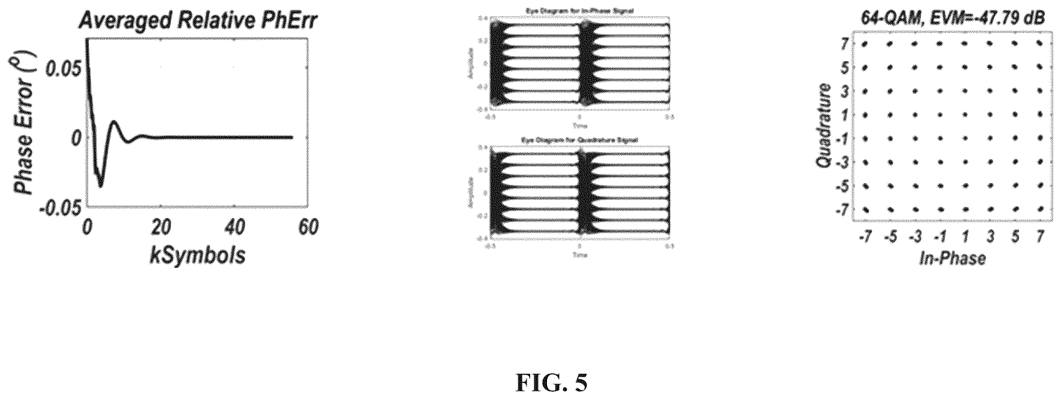

The operation of the invented receiver architecture may be verified in simulation platform using 64QAM example to prove the feasibility. FIG. 4 is a diagram illustrating an N-stage PQD for the demodulation of 4N-QAM in accordance with the systems and methods described herein. A Costas-loop-based carrier synchronization loop with a damping factor of 1 shows successful carrier phase locking, as indicated in FIG. 5. Upon carrier phase locking, the baseband signals at PQD input become a PAM-8 waveform, and the equivalent baseband complex constellation shows good EVM for 64QAM operation.

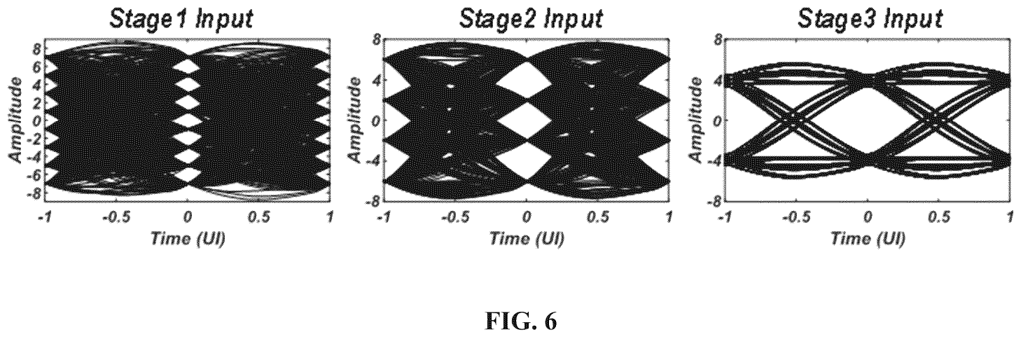

FIG. 5 is a diagram illustrating a carrier phase synchronization and down-converted baseband signal waveform in accordance with the systems and methods described herein. In an example embodiment, the signal waveform going through the pipelined stages in PQD gradually reduces from high order PAM to an NRZ in the final stage. The progress of the signal waveform is shown in FIG. 6 for a 64QAM example. An example embodiment may be extended to an N-stage implementation.

FIG. 6 is a diagram illustrating a baseband signal in each stage of PQD illustrating a demodulation process of a 64QAM Signal in accordance with the systems and methods described herein.

In an example embodiment, the invented receiver architecture may achieve ultra-high-data-rate wireless communication with significantly lower cost and power consumption, especially when scaled to very complex modulation, e.g., 64QAM and above. The main bottleneck of high-speed-resolution and power-hungry ADC design faced by conventional receiver architectures may be completely eliminated. This invention renders itself more scalable compared to conventional solutions. Increasing modulation order by 4× using the invented receiver architecture only involves adding one more pipelined stage. Using a conventional architecture, the ADC resolution has to be increased by more than 6 dB while keeping the same sample rate, an extremely challenging and costly task at a very high speed of operation.

An example embodiment may include a design of future generations of wireless transceivers that can achieve terabit-per-second (Tbps) data rates with high spectral efficiency. In an example embodiment, this project presents a single-channel transceiver architecture that may overcome fundamental drawbacks that may hinder conventional architectures from achieving above 100 gigabit-per-second (Gbps) data rates. An example embodiment may include the first multi-antenna bits-to-RF and RF-to-bits wireless transceivers that can establish 160 Gbps wireless data rate. An example embodiment may impact wireless technology.

Ongoing super-linear growth of the world's population coupled with the worldwide access to the Internet and the general public's tendency to use more bandwidth-intensive applications fuel the urgency to enhance wireless and wired infrastructures to meet these demands. Moreover, the possibility of replacing the costly wired communication infrastructure—such as the tedious task of digging the pavements in densely populated areas and large data centers—with easily deployable wireless connectivity is intriguing. Enabling applications to include (but are not limited to) wireless extension of current/future short-range fiber-optic access networks, intra-chip communications, kiosk downloads, data-centers, and ultra-fast wireless local area networks (WLANs). However, the currently used wireless spectra from low RF (e.g., 400 MHz) to around 10 GHz is too crowded to accommodate any grandiose enhancement of wireless data bandwidth. There has been a great amount of interest raised by both government and private sectors to increase the carrier frequency and tap into the vastly under-utilized spectrum at mm-wave (30-300 GHz) frequency range. One example is the ongoing research-and-development campaign across the world around the lower side of the mm-wave band at 28- and 39-GHz as part of the 5G wireless standard. From a circuit/system design perspective, operation at mm-wave frequencies leads to a reduction in the physical size of the antenna and associated passive components, making it possible to design sophisticated integrated systems incorporating multi-antenna front-ends and baseband back-ends on a single die.

Two general trends—each with its own limitations and challenges—have been conventionally pursued to boost data rate to the Gbps range, e.g., (a) increasing bandwidth and (b) using modulation schemes with higher spectral efficiency. Wideband transceivers that should uphold high performance over a wide bandwidth are power-hungry and extremely difficult to design, as they require broadband radio-frequency (RF) front-end as well as high sampling-rate mixed-signal circuits that can process broadband signals. On the other hand, operation at high carrier frequencies for the purpose of lowering fractional bandwidth (defined as total bandwidth normalized by carrier frequency) encounters many challenges and limitations stemming from the fundamental physics of semiconductor devices (e.g., maximum operation frequency fmax and intrinsic device noise) and wave propagation (e.g., path loss), as will be discussed below.

Alternatively, increasing the modulation order requires lower local-oscillator (LO) phase noise, higher resolution data converters, and higher front-end linearity all of which are increasingly difficult to accomplish at high frequencies. Limitations and challenges associated with high-order modulations at high frequencies beyond 100 GHz will be articulated herein. Furthermore, we will discuss that eventually, the mixed-signal building block in a conventional transceiver consumes multi-watts of power for sampling rates around and above 50 gigasamples-per-second (GS/s). As will be elaborated below, recently published silicon-based transceiver works targeting data rates above 50 Gbps use oversize and expensive test equipment to perform high-order modulation to report such high data rates. Another issue associated with some current systems, besides the need for expensive off-the-shelf equipment to generate high-order modulation 100+ GHz carrier frequency, is that they mandate an extremely linear power amplifier capable of maintaining power-added efficiency (PAE) at significant back off from their peak power. This notion calls for topologies such as a high-order Doherty structure presented recently at much lower frequencies. Such sophisticated topologies unfortunately lead to dramatic degradation of the output power, which is already low to begin with, at near-fmax frequencies, making the design of power amplifiers for conventional transceiver architectures very challenging.

In some embodiments, the disclosed receiver architecture may be designed specifically for ultra-high-speed communication, providing a solution for achieving high data rates without the need for an analog-to-digital converter (ADC) in the signal path. The architecture may include one or more of various components, including a front-end amplification and filtering stage, a quadrature down-conversion mixer, and a pipelined quadrature amplitude modulation (QAM) demodulator (PQD) for signal demodulation.

In an example embodiment, the receiver architecture, the front-end amplification and filtering stage play a role in signal processing. An embodiment may be configured to amplify the received signal while introducing minimal added noise. Additionally, this stage may effectively filters out potential jammer signals from the communication channel, which may ensure the integrity of the received signal.

In some embodiments, the quadrature down-conversion mixer may be a component for signal conversion. The quadrature down-conversion mixer may utilize a local oscillator (LO) signal derived from a carrier synchronization loop to down-convert the amplified and filtered signal to baseband. This down-conversion process may prepare the signal for further demodulation.

The pipelined QAM demodulator (PQD) within the architecture may be responsible for signal demodulation. The PDQ may be specifically designed to handle high-order QAM signals. The PQD can convert a baseband 4N-QAM constellation into 2N lanes of non-return-to-zero (NRZ) bitstreams. This demodulation process enables the extraction of valuable information from the received signal.

In an example embodiment, to ensure accurate demodulation, the receiver architecture may incorporate a carrier synchronization loop. This loop may be responsible for tracking and maintaining synchronization with the carrier phase of the modulated QAM signal. By continuously adjusting the carrier phase, the architecture may ensure the demodulation process is accurate and reliable.

One advantage of some embodiments of the receiver architecture may be the receiver's ability to demodulate any 4N-QAM signal at any arbitrary carrier frequency. This flexibility may make the architecture suitable for various communication applications, allowing the architecture to adapt to different signal types and carrier frequencies.

An interesting aspect of some example embodiments of the receiver architecture may be the absence of high-speed-resolution ADCs in the demodulation process. Instead, the architecture may employ 2N high-speed “sign-check” comparators. In some embodiments, these comparators may play a role in demodulating the 4N-QAM signal efficiently and effectively. By removing the need for high-speed-resolution ADCs, the architecture may eliminate a bottleneck, resulting in more energy-efficient and cost-effective operation in some example embodiments. Moreover, the removal of the ADC bottleneck may increases the communication speed of the system in some embodiments.

Within the pipelined QAM demodulator, the architecture may incorporate additional functionalities such as channel equalization and symbol clock recovery. These mechanisms may enhance the overall performance of the demodulator by compensating for channel distortions and accurately recovering the symbol clock timing in some example embodiments.

In addition to the receiver architecture's technical advantages, in some example embodiments, the receiver architecture may hold significant potential for practical implementation. The receiver may find applications in both wireless and next-generation wireline systems requiring ultra-high data rates. The architecture's effectiveness makes the receiver a promising design for future generations of wireless transceivers, capable of achieving terabit-per-second (Tbps) data rates with high spectral efficiency, in some embodiments.

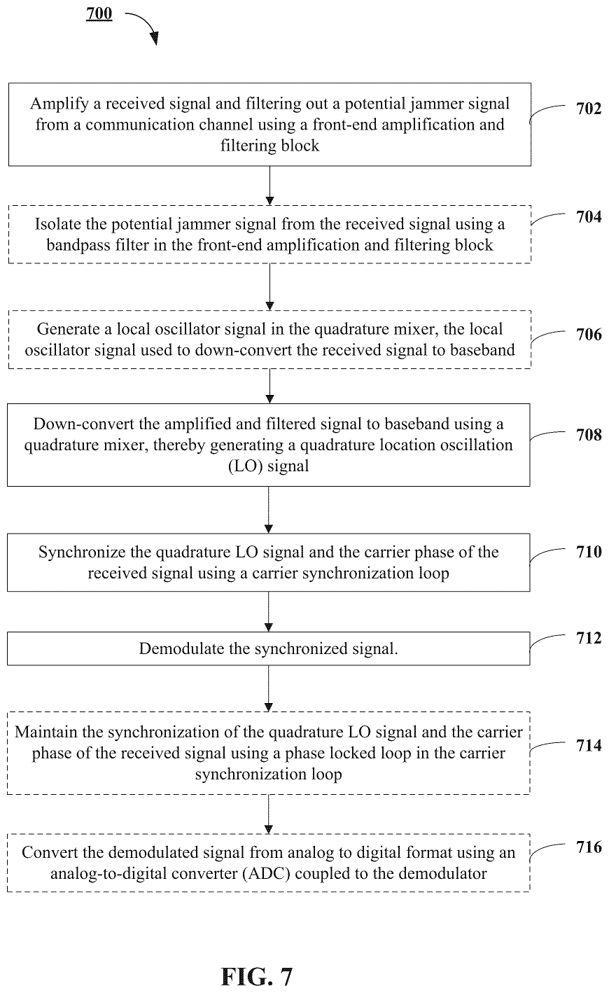

FIG. 7 is a flowchart illustrating an example method 700 in accordance with the systems and methods described herein. The example method may be a method 700 for signal reception in a receiver. The method 700 may include amplifying a received signal and filtering out a potential jammer signal from a communication channel using a front-end amplification and filtering block (702). Optionally, the method 700 may include isolating the potential jammer signal from the received signal using a bandpass filter in the front-end amplification and filtering block (704).

Optionally, the method 700 may include generating a local oscillator signal in the quadrature mixer, the local oscillator signal used to down-convert the received signal to baseband (706). The method 700 may include down-converting the amplified and filtered signal to baseband using a quadrature mixer, thereby generating a quadrature location oscillation (LO) signal (708).

The method 700 may include synchronizing the quadrature LO signal and the carrier phase of the received signal using a carrier synchronization loop (710). The method 700 may include demodulating the synchronized signal (712). Optionally, the method 700 may include maintaining the synchronization of the quadrature LO signal and the carrier phase of the received signal using a phase locked loop in the carrier synchronization loop (714). Optionally, the method 700 may include the demodulated signal from analog to digital format using an analog-to-digital converter (ADC) coupled to the demodulator (716).

The method 700 may include amplifying a received signal and filtering out a potential jammer signal from a communication channel using a front-end amplification and filtering block (702). Amplifying a received signal and filtering out a potential jammer signal from a communication channel using a front-end amplification and filtering block may include receiving a signal that needs to be amplified and filtere and appling amplification to the received signal using a front-end amplification block, which may include increase the strength or amplitude of the signal while minimizing the introduction of additional noise. This step may include employing a front-end filtering block to remove or attenuate unwanted signals, such as potential jammer signals, from the received signal, and/or utilizing a filtering mechanism that selectively blocks or reduces the power of frequencies associated with potential jammers. The step may also include ensuring that the desired signal is preserved and enhanced, while the potential jammer signal is effectively suppressed and/or obtaining the amplified and filtered signal as the output of the front-end amplification and filtering block. The step may include providing the output signal for further processing or analysis in subsequent stages of the receiver system.

Optionally, the method 700 may include isolating the potential jammer signal from the received signal using a bandpass filter in the front-end amplification and filtering block (704).

The process of isolating the potential jammer signal from the received signal using a bandpass filter in the front-end amplification and filtering block (704) may be broken down into one or more of the following sub-steps: considering the received signal that has undergone front-end amplification and filtering, implementing a bandpass filter within the front-end amplification and filtering block, configuring the bandpass filter to allow a specific range of frequencies associated with the potential jammer signal to pass through while attenuating or blocking other frequencies, designing the bandpass filter to have a center frequency and a bandwidth that corresponds to the desired range of frequencies to isolate the potential jammer signal, applying the received signal to the bandpass filter. The bandpass filter selectively passes frequencies within its specified range, which includes the frequencies of the potential jammer signal. The bandpass filter attenuates or blocks frequencies outside its specified range, reducing the impact of unwanted signals or noise.

This step may include obtain the output of the bandpass filter as the isolated potential jammer signal. The isolated signal may include the frequencies associated with the potential jammer signal, while other frequencies, including the desired signal, may be attenuated or removed. The sub-steps mentioned above provide a breakdown of the process of isolating the potential jammer signal using a bandpass filter within the front-end amplification and filtering block.

Optionally, the method 700 may include generating a local oscillator signal in the quadrature mixer, the local oscillator signal used to down-convert the received signal to baseband (706). The process of generating a local oscillator signal in the quadrature mixer, which is used to down-convert the received signal to baseband may be broken down into the following sub-steps:

Consider the quadrature mixer, a component responsible for down-converting the received signal to baseband and/or generating a local oscillator signal within the quadrature mixer. The local oscillator signal serves as a reference signal for the down-conversion process. The step may include designing the local oscillator signal to have a specific frequency and phase relationship with the received signal to enable accurate down-conversion. The step may include combining the received signal with the local oscillator signal in the quadrature mixer. The mixing process may involve multiplying the received signal with the local oscillator signal. The mixing operation may generate sum and difference frequency components. The step may include extracting the baseband signal from the mixed output. The mixing process with the local oscillator signal shifts the frequency content of the received signal to lower frequencies, bringing it to the baseband range.

The down-converted signal represents the original received signal but at baseband frequency. The step may include obtaining the down-converted signal as the output of the quadrature mixer. The down-converted signal is typically further processed or analyzed in subsequent stages of the receiver system. The sub-steps mentioned above provide an example breakdown of the process of generating a local oscillator signal in the quadrature mixer and using it to down-convert the received signal to baseband.

The method 700 may include down-converting the amplified and filtered signal to baseband using a quadrature mixer, thereby generating a quadrature location oscillation (LO) signal (708). The process of down-converting the amplified and filtered signal to baseband using a quadrature mixer and generating a quadrature local oscillator (LO) signal may be broken down into one or more of the following sub-steps: considering the signal that has been amplified and filtered in the previous stages of the receiver, and/or utilizing a quadrature mixer in the receiver architecture. The quadrature mixer is designed to perform frequency conversion by multiplying the amplified and filtered signal with the quadrature LO signal. The step may include generating a quadrature LO signal within the receiver. The LO signal is typically generated by a local oscillator circuit and consists of two signals, an in-phase (I) signal and a quadrature-phase (Q) signal, with a 90-degree phase difference between them. The step may include combining the amplified and filtered signal with the quadrature LO signal in the quadrature mixer. The mixing process involves multiplying the two signals together. The quadrature mixer may generate two output signals: the in-phase component (I_out) and the quadrature-phase component (Q_out).

The step may include extracting the baseband components from the mixer outputs. The in-phase and quadrature-phase components represent the down-converted signal at baseband frequency. These components may carry the amplitude and phase information of the original signal. The step may include generating the quadrature LO signal required for the down-conversion process. The quadrature LO signal may be generated using phase-shifting techniques or by utilizing a local oscillator circuit specifically designed for this purpose. The step may include obtaining the down-converted signal, represented by the in-phase (I_out) and quadrature-phase (Q_out) components, as the output of the quadrature mixer. The down-converted signal may then be further processed or utilized in subsequent stages of the receiver for demodulation, decoding, or further analysis. The sub-steps provided above offer an example breakdown of the process of down-converting the amplified and filtered signal to baseband using a quadrature mixer and generating a quadrature LO signal.

The method 700 may include synchronizing the quadrature LO signal and the carrier phase of the received signal using a carrier synchronization loop (710). The process of synchronizing the quadrature LO signal and the carrier phase of the received signal using a carrier synchronization loop may be broken down into one or more of the following sub-steps: considering the quadrature LO signal generated in the previous stages of the receiver. The quadrature LO signal consists of in-phase (I) and quadrature-phase (Q) components. Taking the received signal that has been down-converted to baseband using the quadrature mixer. Implementing a carrier synchronization loop in the receiver architecture. The carrier synchronization loop is responsible for adjusting the carrier phase of the received signal to match the quadrature LO signal. Utilizing a phase detector within the carrier synchronization loop. The phase detector compares the phase difference between the quadrature LO signal and the received signal. Calculating the error signal based on the phase difference detected by the phase detector. The error signal represents the deviation between the carrier phase of the received signal and the quadrature LO signal. Applying a loop filter to the error signal. The loop filter smoothes and filters the error signal to provide a stable control input to the carrier synchronization loop. Feeding the filtered error signal as a control input to the carrier synchronization loop. The control input adjusts the carrier phase of the received signal to align it with the quadrature LO signal. Closing the feedback loop by applying the adjusted carrier phase to the received signal. The adjusted carrier phase ensures that the received signal is properly synchronized with the quadrature LO signal. Allowing the carrier synchronization loop to iteratively adjust the carrier phase until convergence is achieved. The loop continuously refines the carrier phase alignment between the received signal and the quadrature LO signal. Obtaining the synchronized signal with aligned carrier phase as the output of the carrier synchronization loop. The synchronized signal is now ready for further demodulation or processing stages in the receiver. The sub-steps provided above offer an example breakdown of the process of synchronizing the quadrature LO signal and the carrier phase of the received signal using a carrier synchronization loop.

The method 700 may include demodulating the synchronized signal (712). The process of demodulating the synchronized signal may be broken down into one or more of the following sub-steps: taking the synchronized signal obtained from the carrier synchronization loop. Utilizing a de todulator component in the receiver architecture. The demodulator is responsible for extracting the information or data from the synchronized signal. Determining the demodulation scheme used for the specific communication system. The demodulation scheme depends on the modulation technique employed in the transmitter. Applying signal processing techniques to the synchronized signal. The signal processing may involve filtering, equalization, or other operations specific to the demodulation scheme. Detecting the symbols or data embedded in the synchronized signal. The demodulator identifies the transmitted symbols based on the characteristics of the received signal. Decoding the detected symbols to obtain the original information or data. The symbol decoding process reconstructs the transmitted information from the demodulated symbols. Obtaining the demodulated data or information as the output of the demodulation process. The output represents the recovered information from the synchronized signal. The sub-steps provided above offer an example breakdown of the process of demodulating the synchronized signal. The specific details of each sub-step may vary depending on the modulation scheme and receiver architecture employed in the communication system.

Optionally, the method 700 may include maintaining the synchronization of the quadrature LO signal and the carrier phase of the received signal using a phase locked loop in the carrier synchronization loop (714). The process of maintaining the synchronization of the quadrature LO signal and the carrier phase of the received signal using a phase-locked loop (PLL) in the carrier synchronization loop can be broken down into the following sub-steps: utilizing a PLL as a control system within the carrier synchronization loop. A PLL is a feedback system that compares the phase of the quadrature LO signal and the carrier phase of the received signal. Performing a phase comparison between the quadrature LO signal and the carrier phase of the received signal. The phase comparison determines the phase difference between the two signals. Detecting the phase error between the quadrature LO signal and the carrier phase. The error detection mechanism measures the deviation between the desired synchronization and the actual synchronization. Employing a loop filter to process the error signal obtained from the phase comparison. The loop filter adjusts the gain and dynamics of the control system to stabilize the synchronization. Utilizing a VCO as part of the PLL in the carrier synchronization loop. The VCO generates the quadrature LO signal and its frequency is adjusted based on the control signal from the loop filter. Providing a feedback loop from the VCO to the phase comparison. The feedback loop adjusts the phase of the quadrature LO signal based on the error signal, aiming to minimize the phase difference. Continuously monitoring the synchronization status between the quadrature LO signal and the carrier phase. The carrier synchronization loop maintains the synchronization by continuously adjusting the VCO frequency and compensating for any phase discrepancies. The sub-steps provided above offer an example breakdown of the process of maintaining synchronization using a PLL in the carrier synchronization loop. The specific details of each sub-step may vary depending on the implementation of the PLL and the receiver architecture.

Optionally, the method 700 may include converting the demodulated signal from analog to digital format using an analog-to-digital converter (ADC) coupled to the demodulator (716). The process of converting the demodulated signal from analog to digital format using an ADC coupled to the demodulator may be broken down into one or more the following sub-steps. (It will be understood that many embodiments do not include an ADC. However, some embodiments may an ADC to perform the converting of the demodulated signal from analog to digital format using an ADC.)

Some examples may obtain the demodulated signal outputted by the demodulator. The demodulated signal represents the recovered information from the received modulated signal. The embodiment may connect an analog-to-digital converter (ADC) to the output of the demodulator. The ADC may be responsible for converting the continuous analog signal into discrete digital samples. The embodiment may sample the demodulated analog signal at regular intervals. The sampling process captures the amplitude of the analog signal at specific time points. The example embodiment may quantize the sampled analog signal by assigning discrete digital values to each sample. The quantization process may involve mapping the analog signal's amplitude range into a finite set of digital values. The example embodiment may encode the quantized digital values into a digital representation. This coding step may involve techniques such as binary encoding or other digital coding schemes. The embodiment maybe obtain the digital representation of the demodulated signal. The digital output represents the demodulated signal in a format suitable for digital processing and further analysis. The sub-steps provided above offer an example breakdown of the process of converting the demodulated signal from analog to digital format using an ADC. The specific details of each sub-step may vary depending on the characteristics and parameters of the ADC and the demodulated signal being processed.

One or more of the components, steps, features, and/or functions illustrated in the figures may be rearranged and/or combined into a single component, block, feature or function or embodied in several components, steps, or functions. Additional elements, components, steps, and/or functions may also be added without departing from the disclosure. The apparatus, devices, and/or components illustrated in the Figures may be configured to perform one or more of the methods, features, or steps described in the Figures. The algorithms described herein may also be efficiently implemented in software and/or embedded in hardware.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description are presented in terms of algorithms and symbolic representations of operations on data bits within a computer memory. These algorithmic descriptions and representations are the methods used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared or otherwise manipulated. It has proven convenient at times, principally for reasons of common usage, to refer to these signals as bits, values, elements, symbols, characters, terms, numbers or the like.

It should be borne in mind, however, that all of these and similar terms are to be associated with the appropriate physical quantities and are merely convenient labels applied to these quantities. Unless specifically stated otherwise as apparent from the following disclosure, it is appreciated that throughout the disclosure terms such as “processing,” “computing,” “calculating,” “determining,” “displaying” or the like, refer to the action and processes of a computer system, or similar electronic computing device, that manipulates and transforms data represented as physical (electronic) quantities within the computer system's registers and memories into other data similarly represented as physical quantities within the computer system's memories or registers or other such information storage, transmission or display.

Finally, the algorithms and displays presented herein are not inherently related to any particular computer or other apparatus. Various general-purpose systems may be used with programs in accordance with the teachings herein, or it may prove convenient to construct more specialized apparatus to perform the required method steps. The required structure for a variety of these systems will appear from the description below. It will be appreciated that a variety of programming languages may be used to implement the teachings of the invention as described herein.

The figures and the following description describe certain embodiments by way of illustration only. One skilled in the art will readily recognize from the following description that alternative embodiments of the structures and methods illustrated herein may be employed without departing from the principles described herein. Reference will now be made in detail to several embodiments, examples of which are illustrated in the accompanying figures. It is noted that wherever practicable similar or like reference numbers may be used in the figures to indicate similar or like functionality.

The foregoing description of the embodiments of the present invention has been presented for the purposes of illustration and description. It is not intended to be exhaustive or to limit the present invention to the precise form disclosed. Many modifications and variations are possible in light of the above teaching. It is intended that the scope of the present invention be limited not by this detailed description, but rather by the claims of this application. As will be understood by those familiar with the art, the present invention may be embodied in other specific forms without departing from the spirit or essential characteristics thereof. Likewise, the particular naming and division of the modules, routines, features, attributes, methodologies and other aspects are not mandatory or significant, and the mechanisms that implement the present invention or its features may have different names, divisions and/or formats.

Furthermore, as will be apparent to one of ordinary skill in the relevant art, the modules, routines, features, attributes, methodologies and other aspects of the present invention can be implemented as software, hardware, firmware or any combination of the three. Also, wherever a component, an example of which is a module, of the present invention is implemented as software, the component can be implemented as a standalone program, as part of a larger program, as a plurality of separate programs, as a statically or dynamically linked library, as a kernel loadable module, as a device driver, and/or in every and any other way known now or in the future to those of ordinary skill in the art of computer programming.

Additionally, the present invention is in no way limited to implementation in any specific programming language, or for any specific operating system or environment. Accordingly, the disclosure of the present invention is intended to be illustrative, but not limiting, of the scope of the present invention, which is set forth in the following claims.

It is understood that the specific order or hierarchy of blocks in the processes/flowcharts disclosed is an illustration of example approaches. Based upon design preferences, it will be understood that the specific order or hierarchy of blocks in the processes/flowcharts may be rearranged. Further, some blocks may be combined or omitted. The accompanying method claims present elements of the various blocks in a sample order and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

1. A receiver, comprising:
a front-end amplification and filtering block configured to amplify a received signal and filter out a potential jammer signal from a communication channel;
a quadrature mixer, coupled to the front-end amplification and filtering block, and configured to down-convert the amplified and filtered signal to baseband to generate a quadrature location oscillation (LO) signal;
a carrier synchronization loop configured to synchronize the quadrature LO signal and carrier phase of the received signal; and
a demodulator coupled to the quadrature mixer and the carrier synchronization loop.

2. The receiver of claim 1, further comprising a digital signal processor (DSP) coupled to the demodulator, configured to perform digital signal processing on the demodulated signal.

3. The receiver of claim 2, wherein the digital signal processing includes channel decoding, error correction, or equalization of the demodulated signal.

4. The receiver of claim 1, wherein the front-end amplification and filtering block comprises one or more low-noise amplifiers and one or more bandpass filters.

5. The receiver of claim 1, wherein the quadrature mixer comprises a local oscillator (LO) signal generator and mixers for generating in-phase and quadrature components of the down-converted signal.

6. The receiver of claim 1, wherein the carrier synchronization loop comprises a phase-locked loop (PLL) or a frequency-locked loop (FLL) for tracking and adjusting the carrier phase of the received signal.

7. The receiver of claim 1, further comprising an antenna for receiving the signal from the communication channel.

8. The receiver of claim 1, wherein the demodulator is configured to demodulate the down-converted signal using a modulation scheme selected from the group consisting of amplitude modulation (AM), frequency modulation (FM), phase modulation (PM), or quadrature amplitude modulation (QAM).

9. The receiver of claim 1, further comprising a jammer detection module coupled to the front-end amplification and filtering block, configured to detect the presence of a jammer signal and provide a jammer detection signal to the quadrature mixer for jammer suppression.

10. The receiver of claim 1, wherein the demodulator is implemented as a software-defined radio (SDR) demodulator.

11. The receiver of claim 1, further comprising a power control circuit configured to adjust the amplification level of the front-end amplification and filtering block based on the received signal strength.

12. The receiver of claim 1, further comprising an automatic gain control (AGC) circuit configured to dynamically adjust the gain of the front-end amplification and filtering block to maintain a desired signal level at the quadrature mixer.

13. The receiver of claim 1, further comprising a frequency synthesis circuit for generating the quadrature LO signal based on a reference frequency and a frequency control signal.

14. The receiver of claim 1, wherein the quadrature LO signal is adjusted based on a frequency offset estimation obtained from the carrier synchronization loop.

15. The receiver of claim 1, further comprising a noise reduction module coupled to the demodulator, configured to reduce noise in the demodulated signal using techniques such as filtering or adaptive noise cancellation.

16. A method for signal reception in a receiver, the method comprising:
amplifying a received signal and filtering out a potential jammer signal from a communication channel using a front-end amplification and filtering block;
down-converting the amplified and filtered signal to baseband using a quadrature mixer, thereby generating a quadrature location oscillation (LO) signal;
synchronizing the quadrature LO signal and the carrier phase of the received signal using a carrier synchronization loop; and
demodulating the synchronized signal.

17. The method of claim 1, further comprising isolating the potential jammer signal from the received signal using a bandpass filter in the front-end amplification and filtering block.

18. The method of claim 1, further comprising generating a local oscillator signal in the quadrature mixer, the local oscillator signal used to down-convert the received signal to baseband.

19. The method of claim 1, further comprising maintaining the synchronization of the quadrature LO signal and the carrier phase of the received signal using a phase locked loop in the carrier synchronization loop.

20. The method of claim 1, further comprising converting the demodulated signal from analog to digital format using an analog-to-digital converter (ADC) coupled to the demodulator.
